(19) United States
(12) Patent Application Publication
(10) Pub. No.: US 2007/0118311 A1
(43) Pub. Date: May 24, 2007

(54) Voltage sense apparatus and method for a capacitor charger

(76) Inventor: Yuan-Huang Cheng, Pingdung City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/652,112

(22) Filed: Jan. 11, 2007

Related U.S. Application Data
(62) Division of application No. 11/166,133, filed on Jun. 27, 2005.

(30) Foreign Application Priority Data
Jun. 28, 2004 (TW) 093118878

(51) Int. Cl. G01R 19/00

(52) U.S. Cl. 702/64

(57) ABSTRACT

In a capacitor charger including a transformer to transform a primary coil voltage to a secondary coil voltage to charge a capacitor at an output through a charging node to approach a predetermined voltage, a voltage sense apparatus and method comprise sensing the voltage on the capacitor with a voltage divider to generate a feedback signal to stop charging the capacitor when the capacitor voltage is sensed to be equal to or higher than the predetermined voltage, and preventing an inverse current flowing from the capacitor to the charging node for no leakage occurred from the capacitor to the voltage sense apparatus.

### RELATED APPLICATIONS

This application is a Divisional patent application of co-pending application Ser. No. 11/166,133, filed on 27 Jun. 2005.

### FIELD OF THE INVENTION

The present invention is related generally to a capacitor charger and more particularly to a voltage sense apparatus and method for a capacitor charger. BACKGROUND OF THE INVENTION

Capacitor charger receives more and more attentions due to the gradually popular portable apparatus. A typical application of capacitor charger is for the power supply of flash lamp module. Conventionally, as shown in FIG. 1, a capacitor charger 100 for a flash lamp module has a transformer 102 including a primary coil L₁ and a secondary coil L₂ with the turns ratio of N_{P}:N_{S}, to transform the primary coil voltage V_{bat} to a secondary coil voltage V_{S}, to charge a capacitor C_{O} through a diode 104, to supply the electric power for a flash lamp module 106 connected to an output Vout. An integrated circuit 108 has a transistor M₁ connected between the primary coil L₁ and ground GND and a driver 112 controlled by a control circuit 110 to switch the transistor M₁ for the power delivery of the transformer 102 to the output Vout. To sense the capacitor voltage Vout, two resistors R₁ and R₂ are connected between the output Vout and ground GND to divide the capacitor voltage Vout to generate a feedback signal V_{FB} to a comparator 114 in the integrated circuit 108 to compare with a reference V_{ref} to generate a comparison signal S for the control circuit 110 to switch the transistor M₁. When the capacitor voltage Vout reaches a predetermined level, the charger 100 will stop charging the capacitor C_{O}.

For the power delivery, the operations of the charger 100 shown in FIG. 1 are illustrated by FIGS. 2 and 3. When the transistor M₁ conducts a current I₁, as shown in FIG. 2, energy is stored into the primary coil L₁, both the voltage V_{S} and current I₂ of the secondary coil L₂ are zero. When the transistor M₁ turns off, as shown in FIG. 3, the secondary coil L₂ releases the stored energy to produce a current I₂ flowing through the diode 104 to charge the capacitor C_{O}. Once the capacitor voltage Vout reaches or exceeds the predetermined level, the feedback signal V_{FB} is equal to or larger than the reference V_{ref}, and the output S of the comparator 116 signals the control circuit 110 to stop charging the capacitor C_{O}. However, since the resistors R₁, and R₂ are connected between the output Vout and ground GND, there is always a leakage path therewith, as shown in FIG. 4, through which a leakage current I_{Loss} flows from the capacitor C_{O} to ground GND, resulting in a voltage drop of the capacitor voltage Vout and power loss from the capacitor C_{O}.

To reduce such leakage power loss, Schenkel et al. proposed a capacitor charger circuit in U.S. Pat. No. 6,518,733, by sensing the primary coil voltage to determine when to stop charging the capacitor. Even this art removes the mentioned power loss from the voltage sense apparatus, it has the whole circuit to be complicated and huge.

Therefore, it is desired a simple and lossless voltage sense apparatus and method for a capacitor charger.

### SUMMARY OF THE INVENTION

One object of the present invention is to provide a lossless voltage sense apparatus and method for a capacitor charger.

In a capacitor charger including a transformer to transform a primary coil voltage to a secondary coil voltage to charge a capacitor at an output through a charging node to approach a predetermined voltage, according to the present invention, a voltage sense apparatus and method comprise sensing the voltage on the capacitor with a voltage divider to generate a feedback signal for the capacitor charger to stop charging the capacitor when the capacitor voltage is sensed to be equal to or higher than the predetermined voltage, and preventing an inverse current flowing from the capacitor to the charging node by a rectifier circuit. As a result, the capacitor is prevented from current leakage and power loss through the voltage sense apparatus.

Alternatively, in a capacitor charger including a transformer to transform a primary coil voltage to a secondary coil voltage to charge a capacitor at an output through a charging node to approach a predetermined voltage, a voltage sense apparatus and method according to the present invention comprise drawing a taper from the secondary coil, dividing the voltage on the taper with a voltage divider to generate a feedback signal for the capacitor charger to stop charging the capacitor when the capacitor voltage is sensed to be equal to or higher than the predetermined voltage, and preventing an inverse current flowing from the capacitor to the charging node by a rectifier circuit. As a result, the capacitor is prevented from current leakage and power loss through the voltage sense apparatus. This voltage sense apparatus and method allow the resistors used for the voltage divider to have smaller resistance and volume.

### BRIEF DESCRIPTION OF DRAWINGS

These and other objects, features and advantages of the present invention will become apparent to those skilled in the art upon consideration of the following description of the preferred embodiments of the present invention taken in conjunction with the accompanying drawings, in which:

FIG. 1 shows a circuit diagram of a conventional capacitor charger for a flash lamp module;

FIG. 2 shows the capacitor charger of FIG. 1 when the transistor M1 turns on;

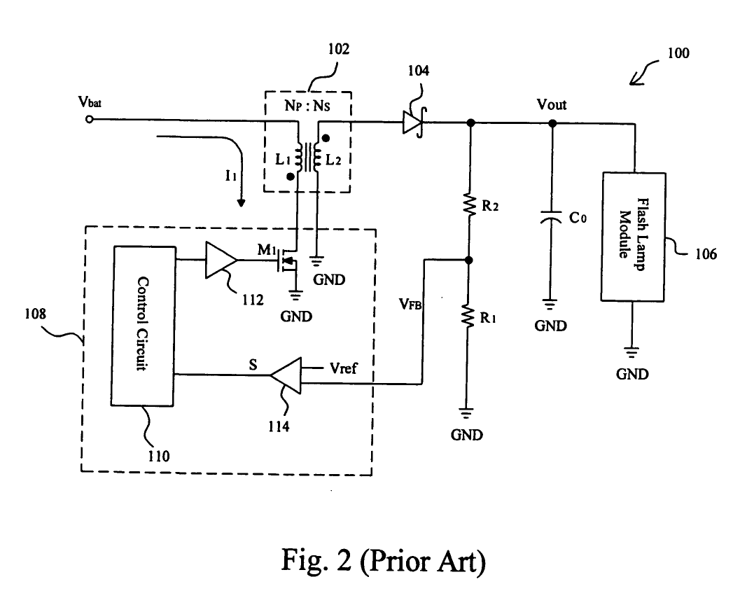

FIG. 3 shows the capacitor charger of FIG. 1 when the transistor M1 turns off;

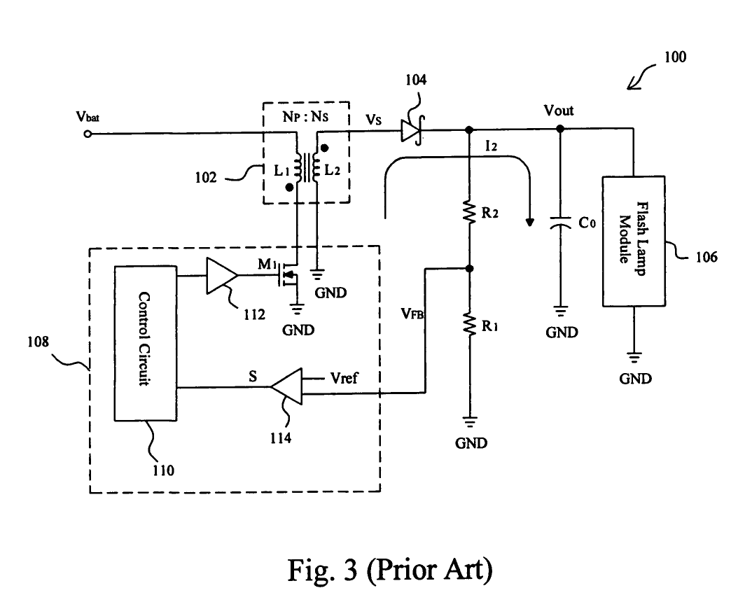

FIG. 4 shows the leakage occurred in the capacitor charger of FIG. 1;

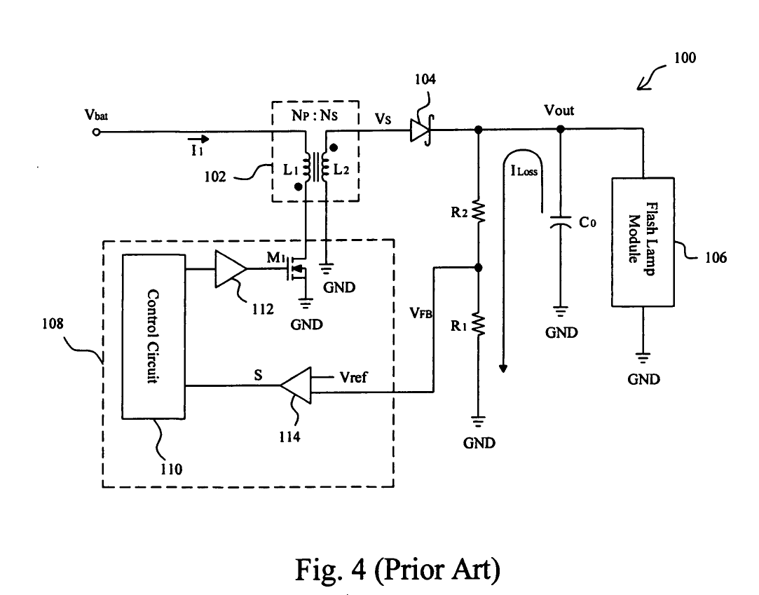

FIG. 5 shows a first embodiment of a voltage sense apparatus and method applied for a capacitor charger according to the present invention; and

FIG. 6 shows a second embodiment of a voltage sense apparatus and method applied for a capacitor charger according to the present invention.

### DETAILED DESCRIPTION OF THE INVENTION

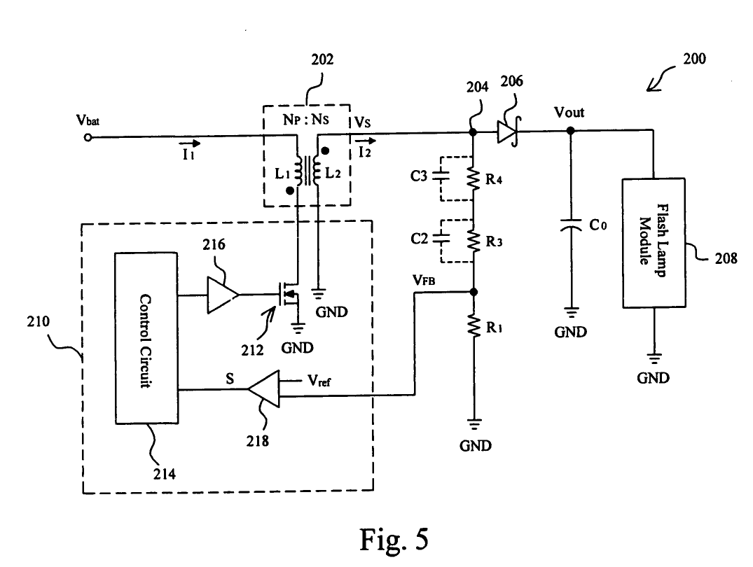

FIG. 5 shows a first embodiment of a voltage sense apparatus and method according to the present invention. In a capacitor charger 200, a transformer 202 has a primary coil L₁ and a secondary coil L₂ with a turns ratio of N_{P}:N_{S} to transform the primary coil voltage V_{bat} to a secondary coil voltage V_{S}, through a charging node 204 to charge a capacitor C_{O} connected to an output Vout to supply for a flash lamp module 208, an integrated circuit 210 has a transistor 212 connected between the primary coil L₁ and ground GND and a driver 216 controlled by a control circuit 214 to switch the transistor 212 for the power delivery of the transformer 202 to the output Vout. To sense the capacitor voltage Vout, resistors R₁, R₃ and R₄ are connected between the charging node 204 and ground GND in such a manner that the resistor R₁, is connected between a feedback node V_{FB} and ground GND to generate a feedback signal V_{FB}, and the other resistors R₃ and R₄ are connected in series between the charging node 204 and feedback node V_{FB}. A small voltage drop across the forward-biased diode 206 is present between the charging node 204 and output Vout, and may be neglected. The feedback signal V_{FB} is compared with a reference V_{ref} by a comparator 218 in the integrated circuit 210 to produce a comparison signal S for the control circuit 214. Once the capacitor voltage Vout reaches or exceeds a predetermined level, the feedback signal V_{FB} will be equal to or larger than the reference V_{ref}, and the output S of the comparator 218 will signal the control circuit 214 to stop charging the capacitor C_{O}. The diode 206 between the charging node 204 and output Vout prevents the capacitor C_{O} from leakage to the charging node 204, and the resistors R₁, R₃ and R₄ for the voltage sense will not cause any leakage or power loss of the capacitor C_{O} since they are connected to the charging node 204.

Referring to FIG. 5, when the transistor 212 conducts a current I₁, it is determined the output voltage

$$V out = ( - {V}_{bat} ) \times \frac{{N}_{S}}{{N}_{P}} , \qquad [ EQ \text{-} 1 ]$$

which is a negative voltage, and therefore the current I₂ flows from ground GND to the transformer 202 through the resistors R₁, R₃ and R₄, thereby generating the feedback signal by voltage dividing theory

$${V}_{FB} = Vout \times \frac{{R}_{1}}{{R}_{1} + {R}_{3} + {R}_{4}} . \qquad [ EQ \text{-} 2 ]$$

By substituting the equation EQ-1 to the equation EQ-2, it is obtained

$${V}_{FB} = - {V}_{bat} \times \frac{{N}_{S}}{{N}_{P}} \times \frac{{R}_{1}}{{R}_{2} + {R}_{3} + {R}_{4}} , \qquad [ EQ \text{-} 3 ]$$

which is a negative voltage. When the transistor 212 turns off, the current I₂ flows from the transformer 202 to the capacitor C_{O}, thereby charging the capacitor C_{O}, and the feedback signal V_{FB} is as shown in the equation EQ-2. Once the capacitor C_{O} is charged to a predetermined level, the feedback signal V_{FB} will be equal to or larger than the reference V_{ref}, and therefore the output S of the comparator 218 will signal the control circuit 214 to stop charging the capacitor C_{O}. Even the capacitor voltage Vout is charged to a high level, with the diode 206 between the charging node 204 and output Vout, the capacitor C_{O} is prevented from leakage to ground GND through the resistors R₁, R₃ and R₄.

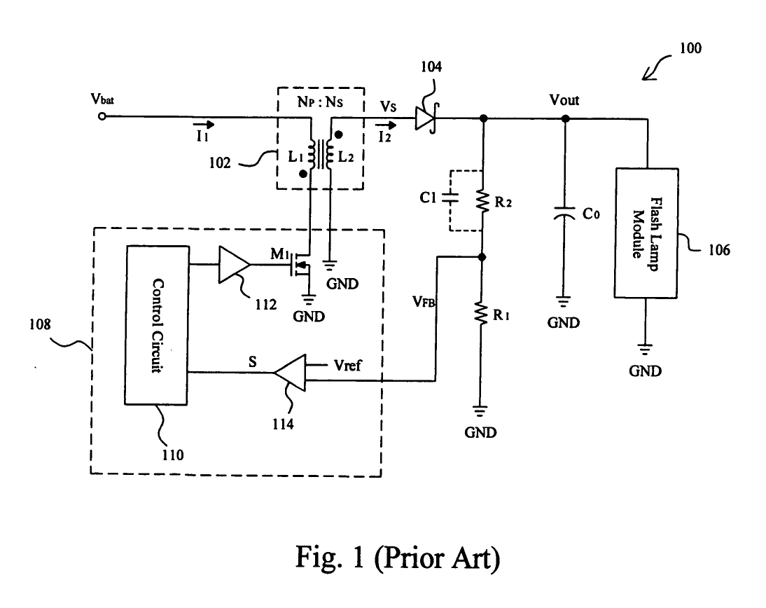

Referring to FIGS. 1 and 5, the combination of the resistors R₃ and R₄ in the charger 200 is equivalent to the resistor R₂ in the charger 100 in their resistance, however, the parasitic capacitance is reduced in the charger 200. Each resistor has a parasitic capacitance, which is proportional to the resistance of the resistor, and therefore the capacitance C₁ parasitic to the resistor R₂ is larger than the capacitance C₂ parasitic to the resistor R₃ and the capacitance C₃ parasitic to the resistor R₄. The larger a capacitance is, the significant the capacitive effect will be. More significant capacitive effect is easier to produce error operations. For example, with a predetermined threshold of 300V for the capacitor voltage Vout to stop charging the capacitor C_{O}, a significant capacitive effect may result in earlier stop of charging the capacitor C_{O} before the capacitor voltage Vout reaches 300V. In the charger 200, the resistors R₃ and R₄ are used to replace the resistor R₂, and therefore the equivalent parasitic capacitance C₄ will have a value determined by

$$\frac{1}{{C}_{4}} = \frac{1}{{C}_{2}} + \frac{1}{{C}_{3}} , \qquad [ EQ \text{-} 4 ]$$

and it is obtained

$${C}_{4} = \frac{{C}_{2} {C}_{3}}{{C}_{2} + {C}_{3}} . \qquad [ EQ \text{-} 5 ]$$

From the equation EQ-5, the equivalent capacitance C₄ is smaller than the capacitances C₂ and C₃, and is therefore smaller than the capacitance C₁. In other words, the charger 200 will have less significant capacitive effect.

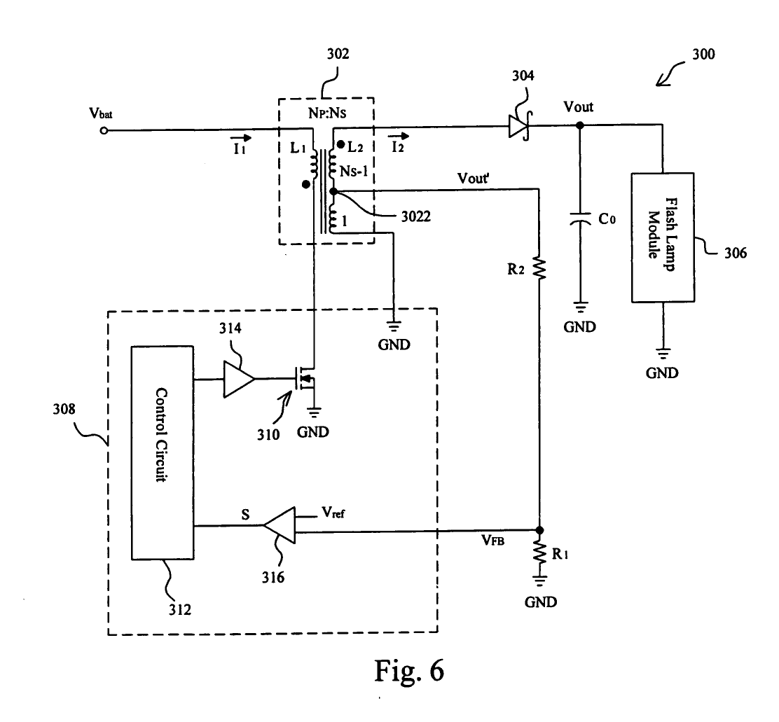

FIG. 6 shows a second embodiment of a voltage sense apparatus and method according to the present invention. In a capacitor charger 300, a transformer 302 has a primary coil L₁ and a secondary coil L₂ with a turns ratio of N_{P}:N_{S} to transform the primary coil voltage V_{bat} to a secondary coil voltage V_{L2}, through a diode 304 to charge a capacitor C_{O} connected to an output Vout to supply for a flash lamp module 306, an integrated circuit 308 has a control circuit 312 to control a driver 314 to switch a transistor 310 connected between the primary coil L₁ and ground GND for the power delivery of the transformer 302 to the output Vout. To sense the capacitor voltage Vout, a taper 3022 is drawn from the secondary coil L₂, with which the secondary coil L₂ is separated to a segment of one turn and a segment of N_{S}-1 turns, and two resistors R₁, and R₂ are connected between the taper 3022 and ground GND to divide the voltage Vout′ on the taper 3022 to generate a feedback signal V_{FB} on a feedback node V_{FB}. In the integrated circuit 308, a comparator 316 compares the feedback node V_{FB} with a reference V_{ref} to generate a comparison signal S to signal the control circuit 312 to stop charging the capacitor C_{O} when the capacitor voltage Vout is equal to or larger than a predetermined threshold.

When the transistor 310 turns off, the capacitor C_{O} is charged by the current I₂, resulting in the feedback signal

$${V}_{FB} = V {out}^{′} \times \frac{{R}_{1}}{{R}_{1} + {R}_{2}} . \qquad [ EQ \text{-} 6 ]$$

Since the two segments of the secondary coil L₂ have the turns ratio of 1:N_{S}-1, by neglecting the small voltage drop across the forward-biased diode 304, it is obtained

$$V {out}^{′} = \frac{V out}{{N}_{S}} . \qquad [ EQ \text{-} 7 ]$$

By substituting the equation EQ-7 to the equation EQ-6, it is obtained

$${V}_{FB} = \frac{V out}{{N}_{S}} \times \frac{{R}_{1}}{{R}_{1} + {R}_{2}} . \qquad [ EQ \text{-} 8 ]$$

From the equation EQ-8, it is shown that the feedback signal V_{FB}is proportional to the capacitor voltage Vout. With the diode 304 between the output Vout and transformer 302, the capacitor C_{O} is prevented from leakage to the voltage sense apparatus.

While the present invention has been described in conjunction with preferred embodiments thereof, it is evident that many alternatives, modifications and variations will be apparent to those skilled in the art. Accordingly, it is intended to embrace all such alternatives, modifications and variations that fall within the spirit and scope thereof as set forth in the appended claims.

What is claimed is:

1. In a capacitor charger including a transformer to transform a primary coil voltage to a secondary coil voltage to charge a capacitor at an output through a charging node to approach a predetermined voltage, a voltage sense apparatus for generating a feedback signal on a feedback node for the capacitor charger to stop charging the capacitor when the capacitor voltage is sensed to be equal to or higher than the predetermined voltage, the voltage sense apparatus comprising:
a taper drawn from the secondary coil;
a voltage divider, connected between the taper and a reference voltage, having a feedback arrangement for generating the feedback signal; and
a rectifier circuit connected between the charging node and output for preventing an inverse current flowing from the capacitor to the charging node.

2. The apparatus of claim 1, wherein the rectifier circuit comprises a diode.

3. The apparatus of claim 1, wherein the feedback arrangement comprises a resistor.

4. In a capacitor charger including a transformer to transform a primary coil voltage to a secondary coil voltage- to charge a capacitor at an output through a charging node to approach a predetermined voltage, a voltage sense method for generating a feedback signal for the capacitor charger to stop charging the capacitor when the capacitor voltage is sensed to be equal to or higher than the predetermined voltage, the voltage sense method comprising the steps of:
preventing an inverse current flowing from the capacitor to the charging node;
drawing a taper from the secondary coil; and
dividing the voltage on the taper for generating the feedback signal.
